(19) United States
(12) Patent Application Publication
(10) Pub. No.: US 2019/0185713 A1
(43) Pub. Date: Jun. 20, 2019

(54) CMP SLURRY COMPOSITIONS CONTAINING SILICA WITH TRIMETHYLSULFOXONIUM CATIONS

(71) Applicant: Rohm and Haas Electronic Materials CMP Holdings, Inc., Newark, DE (US)

(72) Inventor: David Mosley, Lafayette Hill, PA (US)

(21) Appl. No.: 15/842,297

(22) Filed: Dec. 14, 2017

(51) Int. Cl. C09G 1/02; H01L 21/3105

(52) U.S. Cl. CPC C09G 1/02; H01L 21/31053

(57) ABSTRACT

The present invention provides aqueous chemical mechanical planarization (CMP) polishing compositions comprising from 0.25 to 30 wt. % of aqueous colloidal silica particles containing within them trialkylsulfonium groups, trialkylsulfoxonium groups, or both, preferably, trimethylsulfoxonium groups, trimethylsulfonium groups, or both. The compositions have a pH of from 2 to 7, and, further, the colloidal silica particles have a positive zeta potential at a pH of 3.5 and a solids content of 2 wt. % without the need for positively charged unbound additives.

The present invention relates to aqueous chemical mechanical planarization (CMP) polishing compositions comprising colloidal silica particles containing within them trialkylsulfonium groups, trialkylsulfoxonium groups, or both, preferably, trimethylsulfoxonium groups, trimethylsulfonium groups, or both.

Positively charged silica particles have been disclosed and shown to be useful for polishing negatively charged semiconductor wafers because they allow the use of lower concentrations of particles in a slurry. Several known methods of making silica particles which have a cationic nitrogen species inside the particle enable one to alter the isoelectric point of silica particles, thereby allowing the particles to remain positively charged in aqueous solutions at higher pHs than for a silica particle. Depending on the measurement method, a silica particle has an isoelectric point (IEP) of from pH 2-3.1 in water. Silica particles containing trapped cationic nitrogen species can have isoelectric points higher in pH, allowing formulation of polishing slurries at a pH above the silica IEP of ˜3 and below the IEP of the modified silica particles. However, cationic nitrogen compounds have toxicity problems in industrial use. Tetramethylammonium compounds have been responsible for multiple deaths in the semiconductor industry in Taiwan, and the semiconductor industry would like to phase out use of tetramethylammonium and other small nitrogen cationics. These small nitrogen cationics also have extended lifetimes in the environment, causing aquatic toxicity.

U.S. Pat. No. 9,129,907, to White et al. discloses CMP polishing compositions comprising aqueous colloidal silica and at least one onium salt additive selected from a phosphonium salt, a sulfonium salt, or their combination, which compositions have a pH of 5 or less. The compositions exhibit useful oxide removal rates. However, White discloses only an additive approach to improving CMP polishing compositions, which has a limited removal rate benefit compared to particles with charge trapped in or on the particle. Additionally, any freely floating additives used to alter the silica charge may participate in a dynamic binding equilibrium with and so can interfere with other surfaces during CMP polishing. Other surfaces may include the CMP polishing pad, slurry feed lines, the CMP conditioning disk, and the wafer substrate being polished.

The present inventors have endeavored to solve the problem of providing aqueous silica CMP polishing compositions that have a positive zeta potential above pH 3 without the need for a freely floating additive in the slurry to invert the particle charge.

### STATEMENT OF THE INVENTION

1. In accordance with the present invention, aqueous chemical mechanical planarization (CMP) polishing compositions comprise from 0.25 to 30 wt. %, or, preferably, from 0.5 to 24 wt. % of aqueous colloidal silica particles containing within them trialkylsulfonium groups, trialkylsulfoxonium groups, or both, preferably, trimethylsulfoxonium groups, trimethylsulfonium groups, or both, the compositions having a pH of from 2 to 7, or, preferably, from 3 to 4.5, and, further wherein, the particles have a zeta potential of from −2 mV to 40 mV, or, preferably, a positive zeta potential at a pH of 3.5 and a solids content of 2 wt. %.

2. In accordance with the aqueous chemical mechanical planarization (CMP) polishing compositions of the present invention, wherein the particles have a zeta potential of from 1 to 20 mV, or, preferably, from 2 to 15 mV at a pH of 3.5 and a solids content of 2 wt. %.

3. In accordance with the aqueous chemical mechanical planarization (CMP) polishing compositions of the present invention as in any one of items 1 or 2, above, wherein the alkyl groups in the trialkylsulfonium or trialkylsulfoxonium groups comprise, independently C₁ to C₄ alkyl groups, or C₁ to C₄ branched alkyl groups.

4. In accordance with the aqueous chemical mechanical planarization (CMP) polishing compositions of the present invention as in any one of items 1, 2 or 3, above, wherein the aqueous colloidal silica particles further contain one or more aminosilane groups, such as an aminoalkoxysilane, or, preferably, a hydrolysable aminosilane having a secondary amine or tertiary amine group.

5. In accordance with the aqueous chemical mechanical planarization (CMP) polishing compositions of the present invention as in item 4, above, wherein the aqueous aminosilane comprises an aminosilane containing one or more tertiary amine group, such as N,N-(diethylaminomethyl)triethoxysilane (DEAMS), or one or more secondary amine group, such as N-(2-aminoethyl)-3-aminopropyltrimethoxysilane (AEAPS) or N-aminoethylaminoethylaminopropyl trimethoxysilane (DEAPS aka DETAPS).

6. In accordance with the aqueous chemical mechanical planarization (CMP) polishing compositions of the present invention as in any one of items 1, 2, 3 4, or 5, above, wherein the z-average particle sizes (DLS) of the colloidal silica ranges from 24 nm to 250 nm, or, preferably, from 30 nm to 150 nm.

7. The aqueous chemical mechanical planarization (CMP) polishing compositions as in any one of items 1 to 6, above, the compositions further comprising nitric acid or KOH in an amount to adjust the pH.

8. The aqueous chemical mechanical planarization (CMP) polishing compositions as in any one of items 1 to 7, above, for use in polishing dielectrics or oxide containing substrates, wherein the compositions comprise no oxidizer compound, such as iron oxides.

9. In accordance with a second aspect of the present invention, a method of making an aqueous CMP polishing composition comprises: (a1) providing aqueous silicic acid at a pH of below 4.0 at a solids concentration of from 1 to 20, or, preferably, from 2 to 10 wt. %, or (a2) forming the aqueous silicic acid at the same solids concentration as in (a1) by combining an excess of an aqueous cation exchange resin in protonated form containing an acid functional group, such as a sulfonic acid functional ion exchange resin or another acid group functional ion exchange resin capable of protonating silicate anions, such as phosphonic acid, with a silicic acid alkali salt, such as sodium orthosilicate or water glass, in solid form or as an aqueous dispersion of from 5 to 50 wt. % solids to keep the dispersion below a pH of 9, or, preferably, below 8, preferably, by slowly adding the silicic acid alkali salt to the aqueous cation exchange resin and allowing the pH to drop as the alkali metal is consumed by the cation exchange resin; separately, providing a reactive aqueous colloidal silica dispersion at a solids content of from 2 to 20 wt. % solids and a pH of from 2.1 to 4, or, preferably, from 2.5 to 3.5, including, if desired, lowering its pH by treating an aqueous colloidal silica dispersion with a cation exchange resin in protonated form to remove alkali metal and free floating cations; adding a trialkylsulfonium or trialkylsulfoxonium salt or hydroxide, or a mixture thereof, preferably, trimethylsulfonium iodide or hydroxide, or trimethylsulfoxonium iodide or hydroxide, or a mixture thereof to the reactive aqueous colloidal silica dispersion to form a reaction mixture; heating the reaction mixture to a reaction temperature of from 70 to 120° C., or, preferably, from 85 to 115° C., feeding the aqueous silicic acid in to the reaction mixture over time, such as from 30 to 900 minutes, or, preferably, from 30 to 360 minutes to create a partially reacted dispersion of the silicic acid and the colloidal silica; optionally, allowing the reaction mixture to react at the reaction temperature for an additional 30 to 600 minutes, or, preferably, 30 to 300 minutes after the feeding has been completed; rapidly adjusting the pH of the reaction mixture to a pH of from 8 to 10, or, preferably from 9 to 10 to form a basic reaction mixture, optionally, while cooling the reaction mixture to from 20 to 40° C. during the pH adjustment; and, heating the basic reaction mixture to a temperature of from 70 to 120° C., or, preferably, from 85 to 115° C. to polymerize the silicic acid preferably, for a period of from 60 to 600 minutes, or, preferably, from 30 to 300 minutes.

10. In accordance with a second aspect of the present invention, a method of making an aqueous CMP polishing composition comprises: (a1) providing aqueous silicic acid at a pH of below 4.0 and at a solids concentration of from 1 to 20 wt. %, or, preferably, from 2 to 10 wt. %, or (a2) forming the aqueous silicic acid at the same solids content as in (a1) by combining an excess of an aqueous cation exchange resin in protonated form containing an acid functional group, such as a sulfonic acid functional ion exchange resin or another acid group functional ion exchange resin capable of protonating silicate anions, such as phosphonic acid, with a silicic acid alkali salt, such as sodium orthosilicate or water glass, in solid form or as an aqueous dispersion of from 5 to 50 wt. % solids to keep the dispersion below a pH of 9, or, preferably, below 8, preferably, by slowly adding the silicic acid alkali salt to the aqueous cation exchange resin and allowing the pH to drop as the alkali metal is consumed by the cation exchange resin; separately, providing a reactive aqueous colloidal silica dispersion at a solids content of from 2 to 20 wt. % solids and at a pH of from 7 to 11, or, preferably, from 8 to 10; adding a trialkylsulfonium or trialkylsulfoxonium salt or hydroxide, or a mixture thereof, preferably, trimethylsulfonium iodide or hydroxide, or trimethylsulfoxonium iodide or hydroxide, or a mixture thereof to the reactive aqueous colloidal silica dispersion to form a reaction mixture; heating the reaction mixture to a temperature of from 70 to 120° C., or, preferably, from 85 to 115° C., feeding the aqueous silicic acid in to the reaction mixture over time, such as from 30 to 900 minutes, or, preferably, from 30 to 360 minutes; optionally, cofeeding, such as via a separate addition port, an aqueous solution of alkali metal hydroxide, trimethylsulfonium hydroxide, or trimethylsulfoxonium hydroxide into the reaction mixture simultaneously with the aqueous silicic acid to maintain the pH between 7 to 11, or preferably 8 to 10, during the aqueous silicic acid feed; optionally, allowing the reaction mixture to react at a temperature of from 70 to 120° C., or, preferably, from 85 to 115° C. for an additional 30 to 900 minutes, or, preferably, 30 to 300 minutes.

11. In accordance with the method of making the aqueous CMP polishing composition as set forth in any one of items 9 or 10, above, wherein the trialkylsulfonium or trialkylsulfoxonium initially comprises a salt and before adding the trialkylsulfonium and/or trialkylsulfoxonium to the reactive aqueous colloidal silica dispersion, the trialkylsulfonium and/or trialkylsulfoxonium salt is itself treated with a hydroxide group containing cation exchange resin to render the trialkylsulfonium and/or trialkylsulfoxonium in hydroxide form.

12. In accordance with the method of making the aqueous CMP polishing composition as set forth in any one of items 9, 10 or 11, above, wherein the amount of the trialkylsulfonium or trialkylsulfoxonium salt or hydroxide ranges from 1 to 30, or, preferably, from 5 to 20 millimoles sulfonium or sulfoxonium, per mole of silica in the total reactive aqueous colloidal silica dispersion and the aqueous silicic acid.

13. In accordance with the method of making the aqueous CMP polishing composition as set forth in any one of items 9, 10, 11, or 12, above, wherein the amount of cation exchange resin comprises an excess of moles cation exchange groups over the moles of alkali metal in the total aqueous silicic acid and the reactive aqueous colloidal silica dispersion.

14. In accordance with the method of making the aqueous CMP polishing composition as set forth in any one of items 9, 10, 11, 12, or 13, above, wherein the amount of hydroxide group cation exchange resin comprises an excess of moles hydroxide groups over the moles of anions or halides in the trialkylsulfonium and/or trialkylsulfoxonium.

Unless otherwise indicated, conditions of temperature and pressure are ambient temperature and standard pressure. All ranges recited are inclusive and combinable.

Unless otherwise indicated, any term containing parentheses refers, alternatively, to the whole term as if no parentheses were present and the term without them, and combinations of each alternative. Thus, the term “(poly)amine” refers to amine, polyamine, or mixtures thereof.

All ranges are inclusive and combinable. For example, the term “a range of 50 to 3000 cPs, or 100 or more cPs” would include each of 50 to 100 cPs, 50 to 3000 cPs and 100 to 3000 cPs.

As used herein, the term “ASTM” refers to publications of ASTM International, West Conshohocken, Pa.

As used herein, the term “colloidally stable” means that a given composition does not leave a visible sediment or precipitate, and shows less than 100% change in z-average particle diameter as measured by a Malvern DLS instrument after heat aging at 45° C. for 6 days.

As used herein, the term “hard base” refers to metal hydroxides, including alkali(ne earth) metal hydroxides, such as NaOH, KOH, or CsOH.

As used herein, the term “ISO” refers to publications of the International Organization for Standardization, Geneva, CH.

As used herein, the term “silica particle solids” or “silica solids” means, for a given composition, the total amount colloidal silica particles, including anything contained in those particles and anything with which any of those particles are reacted, such as surface treatments.

As used herein, the term “solids” means any material other than water or ammonia that does not volatilize in use conditions, no matter what its physical state. Thus, liquid silanes or additives that do not volatilize in use conditions are considered “solids”.

As used herein, the term “strong acid” refers to protic acids having a pKa of 2 or less, such as inorganic acids like sulfuric or nitric acid.

As used herein, the term “use conditions” means the temperature and pressure at which a given composition is used, including increases in temperature and pressure during use.

As used herein, the term “wt. %” stands for weight percent.

As used herein, the term “z-average particle size (DLS)” means the z-Average particle size of the indicated composition as measured by Dynamic Light Scattering (DLS) using a Malvern Zetasizer device (Malvern Instruments, Malvern, UK) calibrated per manufacturers recommendations. The z-Avg particle size is the intensity-weighted harmonic mean size, which is a diameter, as calculated by an ISO method. (ISO13321:1996 or its newer pendant ISO22412:2008). The term “number average mean diameter” or “(D#)” is calculated using the Malvern non negative least squares distribution analysis with a setting of ‘general purpose,’ 70 size classes, and a regularizer value of 0.01. The non-negative least squares analysis is described by Provencher (S. W. Provencher, Comput. Phys. Commun. 27 (1982), 229). Particle size measurements were made on the concentrated slurries or diluted slurries as described in the examples. Unless otherwise indicated, all particle size measurements were made on slurries diluted to 1% w/w silica particle solids and having a pH ranging from 3.5 to 4.5. The pH of the dilute measured slurry was kept as near as possible to the pH of the concentrate.

As used herein, the term “zeta potential” refers to the charge of a given composition as measured by a Malvern Zetasizer instrument. All zeta potential measurements were made on (diluted) slurry compositions as described in the examples. The reported value was taken from an averaged measurement of zeta values using >20 acquisitions taken by the instrument for each indicated composition.

The present inventors have surprisingly found that aqueous compositions comprising cationic sulfur compound containing colloidal silica particles provide stable CMP polishing compositions having reduced toxicity while maintaining a high removal rate. Because they are more reactive with water than cationic nitrogen compounds, sulfoxonium and sulfonium compounds have shorter lifetimes in aqueous environments than known cationic nitrogen compounds, breaking down to less toxic sulfoxides. The aqueous compositions of the present invention containing the mixture of the silica particles remain colloidally stable at room temperature. Further, the present inventors have found that trialkylsulfonium or trialkylsulfoxonium can be incorporated within a colloidal silica particle during synthesis, altering the isoelectric point of the colloidal silica particle so that it is higher, in the range of from 4 to 6.0. The particles may also have a positive charge of +1 to +15 mV at pH 3.5 and remain positively charged. The present inventors have found that CMP polishing with the colloidal silica particles of the present invention gives a significant improvement in removal rate efficiency versus a non-modified silica particle.

The present inventors have found that trialkylsulfonium or trialkylsulfoxonium can be incorporated within a colloidal silica particle during synthesis. As the term “within” is used herein, the cationic sulfur compound is within a colloidal silica particle when it continues to alter the zeta potential of the silica particle after 3 successive ultrafiltrations, or washes, of the silica particle using an aqueous phase with a pH in the range of 2 to 7 (i.e. the pH range of the inventive composition).

The composition of the present invention has a silicate pore structure or silicate matrix that prevents diffusion of the sulfonium or sulfoxonium groups out of the silica particle in those compositions.

The silica particles suitable for use in accordance with the present invention are colloidal silica particles. A colloidal silica particle is any formed as an aqueous dispersion by inorganic suspension polymerization, such as of water glass processes using alkaline silicate solutions, or by sol-gel polymerization methods using organic precursors such as tetramethylorthosilicate or tetraethylorthosilicate. Both of these methods are conventional in the art.

The colloidal silica particles suitable for use in accordance with the present invention can take any form, including spherical, oblong, bent, nodular or elongated. Spherical, bent, oblong, and nodular particles may be used as a seed for subsequent growth of a sulfoxonium or sulfonium containing silica shell. It is known in the art that bent, oblong, or nodular shaped silica particles may be made by taking advantage of aggregation processes during a silica growth process. The shape of the produced silica particle depends on the growth stage during which a partial aggregation process was performed. Various aggregation methods have been used to create silica particle morphologies, including pH control and one or more additions of divalent cations.

In accordance with the CMP polishing compositions of the present invention, the colloidal silica particle compositions enjoy improved stability at pHs less than 4.5 and a more positive zeta potential. The improved stability and more positive zeta potential expands the useful pH range at which the CMP polishing compositions can effectively be used to polish dielectrics or oxide substrates.

The colloidal silica particles in accordance with the present invention can furthermore be derivatized or treated with aminosilanes post-synthesis.

In accordance with the present invention, suitable amounts of aminosilanes may range from 0.0020 to 0.25 wt. %, or, preferably, from 0.003 to 0.1 wt. % or, more preferably, from 0.003 to 0.02 wt. %, based on the total silica solids in the aqueous CMP polishing compositions.

The colloidal silica particles in accordance with the present invention can further be purified by methods such as ion exchange, ultrafiltration, or centrifugation to remove sulfonium or sulfoxonium salts that are not contained within the silica particles.

To ensure colloidal stability of the aqueous CMP polishing compositions of the present invention, the compositions have a pH ranging from 2 to 7 or, preferably, from 3.0 to 4.5. The compositions tend to lose their stability above the desired pH range.

The composition of the present invention is intended for dielectric polishing, such as interlayer dielectrics (ILD).

### EXAMPLES

The following examples illustrate the various features of the present invention.

In the Examples that follow, unless otherwise indicated, conditions of temperature and pressure are ambient temperature and standard pressure.

The following materials were used in the Examples that follow:

Slurry A: Klebosol™ II 1598-B25 silica (Merck KGaA, Darmstadt, DE);

Cation Exchange Resin: Amberlite™ IRN77 cation exchange resin (anionic polymer with sulfonate groups) (Alfa Aesar, Haverhill, Mass.);

Hydroxide Functional Ion Exchange Resin: Ambersep™ 900 anion exchange resin (anionic polymer with hydroxide groups) (Alfa Aesar, Haverhill, Mass.);

Trimethylsulfoxonium iodide/chloride (Sigma-Aldrich, Milwaukee, Wis.); and,

Trimethylsulfonium iodide (Sigma-Aldrich).

### Synthesis Examples 1 to 17 and 26-29

Reactions as shown in Tables 1, 2, 3 and 6, below, were conducted in vials using a parallel synthesis reactor on a hot plate, so reaction temperature setpoints are approximate; for example, when the reactor setpoint was 101° C., the average composition temperature was lower (±10° C.) due to poor thermal insulation of the vials. For each synthesis example, a 60 mL vial with a magnetic stir bar was used. Deionized (DI) water was mixed with any sulfonium/sulfoxonium composition and then the particle dispersion (as received or as treated with cation exchange resin) was added thereto. The pH was further adjusted as needed using nitric acid or KOH to give an initial pH value. The reactor contents were heated to 101° C. on the hot plate, and then the silicic acid feed was begun. Because of the small volumes, the feed was added in 3 or more equal volume portions over the course of the ‘Reaction time at starting pH’ as shown in Tables 1, 2, 3 and 6, below. For larger scale synthesis processes a gradual feed of the silicic acid would be used by one skilled in the art.

After the ‘Reaction time at starting pH’ in Tables 1, 2, 3 and 6, below, had elapsed, the reactions were briefly cooled and the pH was adjusted to the second pH setpoint. The reactions were then heated back to 101° C. and stirred at 101° C. for the ‘Reaction time at second pH.’ The reactions were then cooled to room temperature and analyzed or tested for polishing as described, below.

Trimethylsulfoxonium Hydroxide (50 millimolar):

Trimethylsulfoxonium hydroxide solution in water was prepared by treating 0.275 g of trimethylsulfoxonium iodide and 24.72 g of DI water with washed hydroxide functional anion exchange resin beads.

Silicic Acid:

Silicic acid was prepared by weighing 115.5 grams of ion exchange resin into a bottle and rinsing with DI water multiple times. To the initial weight of resin, a net total weight of 136.5 grams DI water was added after rinsing. To prevent independent nucleation/formation of a secondary silica dispersion, solid sodium orthosilicate (13.80 g ˜5%, pH 10) powder was added to the cation exchange resin solution in portions to keep the solution below pH 7-8 as much as possible. The final pH achieved was 3.5, and a small amount of HCl was added to further reduce the pH of the active silicic acid solution to 3.0. The silicic acid solution was used for synthesis within 4 hours of generation. Measurement of the particle size of the active silicic acid solution by Malvern DLS instrument (Malvern Instruments, Malvern, UK) gave a number average diameter of 2 nm or less after the ion exchange process.

Silica Dispersion A:

Slurry A as received (pH=8) was mixed with an equal weight of water and treated with cation exchange resin in cation exchange form (protonated) until the pH was below 3.0. The resulting Dispersion had a solids content of 15% w/w. The slurry had a zeta potential of −19.6 mV when measured at pH 3.5 and 0.5% w/w solids. The measured number-average (#-Av) particle size at pH 3.5 and 0.5% w/w solids was 29.2 nm in diameter.

Cation Exchange Resin Treatment of Reaction Mixtures and Products or CER:

For polishing and for some analyses the reactions, after all synthetic steps, were poured over the cation exchange resin to reduce the pH of the product dispersion to ˜pH 2.5-3. This step removes inorganic and organic cations, replacing them with acidic protons.

In each of Tables 1, 2 3, and 6, below, the methods of making the CMP polishing compositions followed from the top row to the bottom row.

### Examples 1-6

For examples 1-6, the quantities and conditions of the reaction are summarized in Table 1, below.

TABLE 1
Synthesis Examples 1 to 6

| | Comp | | | | | |
|---|---|---|---|---|---|---|
| | Ex 1* | Ex 2 | Ex 3 | Ex 4 | Ex 5 | Ex 6 |
| Water (g) | 10.50 | 11.17 | 11.14 | 11.1 | 16.17 | 16.14 |
| Silica Dispersion A (g) | 10.00 | 10.00 | 10.00 | 10.00 | 5.00^{a} | 5.00^{a} |
| Trimethylsulfoxonium Iodide | 0 | 0.0264 | 0.0528 | 0.099 | 0.0264 | 0.0528 |
| (g) | | | | | | |
| Starting pH | 3.0 | 3.0 | 3.0 | 3.0 | 10.0 | 10.0 |
| Silicic acid feed total (g) | 9.50 | 8.80 | 8.80 | 8.80 | 8.80 | 8.80 |
| Silicic acid feed portions | 5 | 3 | 3 | 3 | 3 | 3 |
| Time between feed portions | 60 | 30 | 30 | 30 | 30 | 30 |
| (min) | | | | | | |
| Reaction setpoint Temp (° C.) | 101 | 101 | 101 | 101 | 101 | 101 |
| Reaction time at starting pH | 420 | 120 | 120 | 120 | 120 | 120 |
| (min) | | | | | | |
| Second pH setpoint (KOH | 9 | 9 | 9 | 9 | 9.22^{b} | 9.14^{b} |
| adjusted) | | | | | | |
| Reaction time at second pH | 120 | 120 | 120 | 120 | 120 | 120 |
| (min) | | | | | | |
| Post-rxn zeta potential at pH | −5.88 | −4.23 | −0.66 | 1.32 | −3.96 | −1.15 |
| 3.5 and 0.5% SiO₂ (mv) | | | | | | |
| Post-rxn #-Ave particle size at | 33.4 | 34.7 | 41.1 | 43.8 | 33.8 | 33.6 |
| pH 3.5 and 0.5% SiO₂ (nm) | | | | | | |

*Denotes Comparative Example;
^{a}The particle dispersion was Slurry A, as received with no dilution or treatment;
^{b}The pH was not adjusted, just recorded before second reaction stage.

### Examples 7-12

For examples 7-12, the quantities and conditions of the reaction are summarized in Table 2, below.

TABLE 2
Synthesis Examples 7 to 12

| | Ex 7 | Ex 8 | Ex 9 | Ex 10 | Ex 11 | Ex 12 |
|---|---|---|---|---|---|---|
| Water (g) | 7.96 | 4.75 | 0.25 | 8.20 | 5.20 | 1.00 |
| Silica Dispersion A (g) | 10.00 | 10.00 | 10.00 | 10.00 | 10.00 | 10.00 |
| 50 mm Trimethylsulfoxonium | 3.00 | 6.00 | 10.2 | 3.00 | 6.00 | 10.2 |
| hydroxide (g) | | | | | | |
| 1 molar hydrochloric acid | 0.008 | 0.015 | 0.025 | 0 | 0 | 0 |
| Starting pH^{a} | 3.0 | 3.0 | 3.0 | 10.0 | 10.0 | 10.0 |
| Silicic acid feed total (g) | 8.80 | 8.80 | 8.80 | 8.80 | 8.80 | 8.80 |
| Silicic acid feed portions | 3 | 3 | 3 | 3 | 3 | 3 |
| Time between feed portions | 60 | 30 | 30 | 30 | 30 | 30 |
| (min) | | | | | | |
| Reaction setpoint Temp (° C.) | 101 | 101 | 101 | 101 | 101 | 101 |
| Reaction time at starting pH | 420 | 120 | 120 | 120 | 120 | 120 |
| (min) | | | | | | |
| Second pH setpoint (KOH | 9 | 9 | 9 | 9 | 9 | 9 |
| adjusted) | | | | | | |
| Reaction time at second pH | 120 | 120 | 120 | 120 | 120 | 120 |
| (min) | | | | | | |
| Post-rxn zeta potential at pH | −1.74 | 0 | 1.72 | −1.30 | −1.7 | 1.70 |
| 3.5 and 0.5% SiO₂ (mv) | | | | | | |
| Post-rxn #-Ave particle size at | 39.9 | 37.6 | 46.2 | 37.4 | 33.8 | 36.8 |
| pH 3.5 and 0.5% SiO₂ (nm) | | | | | | |

^{a}The starting pH was set by adjusting with small amounts of HCl or trimethylsulfoxonium hydroxide.

### Examples 13-17

For examples 13-17, the quantities and conditions of the reaction are summarized below. Example 14 was duplicated a total of 4 times and pooled.

TABLE 3
Synthesis Examples 13 to 17

| | Ex 13 | Ex 14 | Ex 15 | Ex 16 | Ex 17 |
|---|---|---|---|---|---|
| Water (g) | 13.05 | 11.10 | 11.17 | 11.14 | 11.10 |
| Silica Dispersion A (g) | 10.00 | 10.00 | 10.00 | 10.00 | 10.00 |
| Trimethylsulfoxonium | 0.099 | 0.099 | 0 | 0 | 0 |
| iodide (g) | | | | | |
| Trimethylsulfonium | 0 | 0 | 0.030 | 0.061 | 0.092 |
| iodide (g) | | | | | |
| Starting pH^{a} | 3.0 | 3.0 | 3.0 | 3.0 | 3.0 |
| Silicic acid feed total (g) | 6.85 | 8.80 | 8.80 | 8.80 | 8.80 |
| Silicic acid feed portions | 3 | 3 | 3 | 3 | 3 |
| Time between feed | 30 | 30 | 30 | 30 | 30 |
| portions (min) | | | | | |
| Reaction setpoint Temp | 101 | 101 | 101 | 101 | 101 |
| ° C.) | | | | | |
| Reaction time at starting | 120 | 120 | 120 | 120 | 120 |
| pH (min) | | | | | |
| Second pH setpoint | 9 | 9 | 9 | 9 | 9 |
| (KOH adjusted) | | | | | |
| Reaction time at second | 180 | 180 | 180 | 180 | 180 |
| pH (min) | | | | | |
| Post-rxn zeta potential at | −3.50 | −1.09^{c} | 2.76 | 5.49 | 6.51 |
| pH 3.5 and 0.5% SiO₂ | | | | | |
| (mv)^{b} | | | | | |
| Post-rxn #-Ave particle | 38.0 | 38.7 | 37.1 | 38.6 | 40.7 |
| size at pH 3.5 and 0.5% | | | | | |
| SiO₂ (nm)^{b} | | | | | |

^{a}The starting pH was set by adjusting with small amounts of hydrochloric acid or potassium hydroxide;
^{b}The particles were treated with fresh rinsed cation exchange resin to reduce ionic strength and remove excess cations in Examples 13-17;
^{c}Value is the average of 4 replicate reactions.

### Example 18

The isoelectric point curve of Examples 14, 17, and unmodified silica dispersion A were measured at 5 wt. % silica solids. The compositions made in Examples 14, 17, and silica dispersion A were all treated with fresh rinsed cation exchange resin prior to measurement. If needed, the pHs were further reduced to pH 2.5 using nitric acid to begin the measurements. After each zeta potential measurement was taken, the pH of each of the compositions was raised by adding KOH and then the next zeta measurement was done

TABLE 4
Zeta Potentials in mV, by pH

| pH | Ex 14 | Ex 17 | Silica Solution A* |
|---|---|---|---|
| 2.5 | 5.92 | 15.1 | −8.23 |
| 3.0 | 5.78 | 12.7 | −6.4 |
| 3.5 | 5.4 | 12.9 | −7.76 |
| 4.0 | 1.55 | 9.38 | −8.6 |
| 4.5 | −1.47 | 4.62 | −9.86 |
| 5.5 | −10.2 | −4.5 | −14.3 |
| 7.5 | −28.4 | −26.5 | −27.4 |
| 9.0 | −37 | −35.8 | −26.5 |

*Denotes Comparative Example.

As shown in Table 4, above, both trimethylsulfoxonium and trimethylsulfonium clearly alter the zeta potential and isoelectric point of the resulting silica particles. With respect to the initial post-reaction zeta potential measurements in Examples 14 and 17 which are lower than the data in this Example 18, zeta potential measurements are sensitive to salt loading and silica particle concentration. Thus, zeta measurements done at low particle concentrations differed from measurements done at more practical concentrations.

### Example 19

Solids from the composition of Example 16 (21.8 grams), which had been treated with freshly rinsed cation exchange resin to remove reaction by-products, were placed in a vial and adjusted to pH 4.0 using potassium hydroxide solution. Separately 8.23 g of water, 0.37 grams of (N,N-diethylaminomethyl)triethoxysilane, and 1.4 grams of 1 normal nitric acid were combined and the pH adjusted, as needed, with extra 1 normal nitric acid to achieve a pH of 4.0. To the 21.8 grams of Ex 16 at pH 4.0 was added 0.14 grams of the hydrolyzed (N,N-diethylaminomethyl)triethoxysilane solution and the resulting solution was stirred at room temperature overnight. After the aminosilane surface reaction, the particles had a zeta potential of 21 mV at pH 3.5, and a number average diameter size of 35.4 nm.

Polishing tests were performed on 5.12 cm (2 inch) square silica wafers using a small scale polishing system consisting of a stationary base, a spinning platen on which the CMP polishing pad sits, a holder for the substrate material and, separately, a conditioning platform having a platen for the CMP polishing pad and a spinning-holder for the conditioning disk. The wafer is placed on a steel holder facing upwards, and the small toroidal pad is mounted on a spinning shaft and presses down on the wafer while immersed in the polishing slurry. Polishing tests were run using a spiral grooved IC1000™ polyurethane CMP polishing pad punch-out. The IC1000™ pad material is a urethane pad 40-80 mils thick with a shore D hardness of 57 (The Dow Chemical Company, Midland, Mich., (Dow)). The pad punch-out is a toroidal disk with a 2.22 cm (0.875 inch) outer diameter and a 0.95 cm (0.375 inch) inner diameter. The pad was textured before polishing by spinning at 300 rpm on a Kinik 150840 diamond disk (Kinik Company, Taiwan) in water using 25.1 kPa (3.65 PSI) downforce for 3 minutes. Silica wafers made by CVD of tetraethylorthosilicate (TEOS wafers) were polished. CMP polishing was done at an rpm of 500 (average 0.41 m/sec across pad ring) in a bath of 10 mL of the indicated slurry. The downforce was 21.4 kPa (3.1 psi). Removal rates were determined by ellipsometry at 4 points around the polish ring both before and after polish. The removal rate of the small scale polisher (in Ang/min) was reported in Table 5 and Table 8, below.

### Examples 20-25

The CMP polishing compositions indicated in Table 5, below, were used to polish a silica (TEOS) wafer and compared to unmodified silica compositions in Comparative Example 20. The indicated pHs were adjusted with nitric or KOH, as needed.

TABLE 5
Removal Rate Comparisons

| Example | Comp Ex 20 | Ex 21 | Ex 22 | Ex 23 | Ex 24 | Ex 25 |
|---|---|---|---|---|---|---|
| Comp | Slurry A | Ex 4 | Ex 4 | Ex 14 | Ex 17 | Ex 19 |
| pH | 3.5 | 3.5 | 4.5 | 3.5 | 3.5 | 4.0 |
| Wt. % | 4 | 4 | 4 | 4 | 4 | 4 |
| silica in | | | | | | |
| slurry | | | | | | |
| Removal | 104^{a} | 434 | 390 | 452^{a} | 371 | 429 |
| Rate | | | | | | |
| (Ang/min) | | | | | | |

^{a}Reported removal rate is the average of 2 separate polishes of the slurry;
* Denotes Comparative Example.

As shown in Table 5, above, the inventive compositions showed a dramatically higher TEOS removal rate versus that in Comparative Example 20.

### Examples 26-29

For examples 26-29, the quantities and conditions of the reaction are summarized in Table 6, below.

TABLE 6
Synthesis of CMP polishing Compositions

| | Ex 26 | Ex 27 | Ex 28 | Ex 29 |
|---|---|---|---|---|
| Water (g) | 11.10 | 11.12 | 16.10 | 16.12 |
| Silica Dispersion A (g) | 10.00 | 10.00 | 5.00^{a} | 5.00^{a} |
| Trimethylsulfoxonium iodide (g) | 0.099 | 0 | 0.099 | 0 |
| Trimethylsulfonium iodide (g) | 0 | 0.076 | 0 | 0.076 |
| Starting pH^{b} | 3.0 | 3.0 | 10.0 | 10.0 |
| Silicic acid feed total (g) | 8.80 | 8.80 | 8.80 | 8.80 |
| Silicic feed portions | 3 | 3 | 3 | 3 |
| Time between feed portions (min) | 30 | 30 | 30 | 30 |
| Reaction setpoint Temp | 101 | 101 | 101 | 101 |
| (C.) | | | | |
| Reaction time at starting pH (min) | 120 | 120 | 120 | 120 |
| Second pH setpoint (KOH | 9 | 9 | 9 | 9 |
| adjusted) | | | | |
| Reaction time at second pH (min) | 240 | 240 | 240 | 240 |
| Post-rxn zeta potential at pH | −0.08 | −2.09 | −1.97 | 7.20 |
| 3.5 and 0.7% SiO₂ (mV) with no | | | | |
| purification treatment | | | | |
| pH after treating reaction mix with | 2.70 | 2.77 | 2.62 | 2.44 |
| CER to remove cations | | | | |
| Zeta potential at pH 3.5 after CER | 2.14 | 9.45 | 0.91 | 7.72 |
| treatment at 1.67% SiO2 (mV) | | | | |
| #-Ave particle size at pH 3.5 and | 37.7 | 38.1 | 33.9 | 34.0 |
| 1.67% SiO₂ (nm) after CER | | | | |
| treatment | | | | |

^{a}The particle dispersion was just as received Klebosol II 1598-B25 with no dilution or treatment.
^{b}The starting pH was set by adjusting with small amounts of hydrochloric acid or potassium hydroxide.

### Examples 30-33: Centrifugation of CMP Polishing Compositions

In examples 30-33, 4 grams of each of the reaction mixtures from examples 26-29 were placed in an Amicon™ Ultra-4 (Millipore Sigma, Danvers, Mass.) centrifugal filtration unit. Each unit had a regenerated cellulose membrane with a nominal molecular weight cutoff of 100 kDaltons. The reaction mixtures were filtered and the centrifugate (centrifugate#1) was analyzed for sulfur onium content by a calibrated gas chromatography method with an approximate limit of detection of 100 ppm. The retained silica particles were resuspended in 3.8 grams of deionized water treated with nitric acid to a pH of 3.5. The resuspended silica particles were filtered through the same centrifugal filtration units and the centrifugate (centrifugate#2) was again analyzed for sulfur onium content. The twice-filtered particles were then resuspended in 3.8 grams of deionized water treated with nitric acid to a pH of 3.5. The zeta potential of the twice-filtered particles were measured, and then the dispersions were filtered a third time. The centrifugate (centrifugate#3) was analyzed for sulfur onium content with none detected, indicating that the zeta potentials of the twice-filtered particles was measured with at least sub-100 ppm levels of sulfur oniums present in the liquid phase, as opposed to sulfur oniums trapped or otherwise very tightly bound to the silica particles. The thrice-filtered particles were then resuspended in 3.8 grams of deionized water treated with nitric acid to a pH of 3.5. The zeta potentials of the thrice-filtered particles were measured, again showing that the inventive compositions retained their positive charge after numerous steps designed to remove unbound sulfur onium species. Assuming each filtration step removed 90% of residual unbound sulfur onium species, the dispersion used for zeta potential measurement of the twice-filtered particles may have had 20-30 ppm of cationic sulfur oniums present in the liquid phase (not within the silica particles), and the dispersion used for zeta potential measurement of the thrice-filtered particles may have had 2-3 ppm of cationic sulfur oniums present in the liquid phase, i.e. not including sulfur onium species within or tightly bound to the silica particles. Analytical test results of the Centrifugates are presented in table 7, below.

TABLE 7
Analysis of Centrifuged CMP Polishing Compositions

| | Ex 30 | Ex 31 | Ex 32 | Ex 33 |
|---|---|---|---|---|
| Reaction mixture treated | 26 | 27 | 28 | 29 |
| Trimethylsulfoxonium iodide in | 3301 | | 3301 | |
| original reaction mixture (ppm) | | | | |
| Trimethylsulfonium iodide in | | 2551 | | 2551 |
| original reaction mixture (ppm) | | | | |
| Trimethylsulfoxonium iodide of | 2560 | | 2300 | |
| centrifugate#1 (ppm) | | | | |
| Trimethylsulfonium iodide of | | 1740 | | 1470 |
| centrifugate#1 (ppm) | | | | |
| Trimethylsulfoxonium iodide of | 310 | | 250 | |
| centrifugate#2 (ppm) | | | | |
| Trimethylsulfonium iodide of | | 250 | | 200 |
| centrifugate#2 (ppm) | | | | |
| Zeta potential of resuspended | −0.73 | 11.1 | −2.06 | 9.01 |
| twice-filtered particles at pH 3.5 | | | | |
| (mV) | | | | |
| Trimethylsulfoxonium iodide of | ND | | ND | |
| centrifugate#3 (ppm) | | | | |
| Trimethylsulfonium iodide of | | ND | | ND |
| centrifugate#3 (ppm) | | | | |
| Zeta potential of thrice-filtered | −1.99 | 7.9 | −3.24 | 6.14 |
| particles at pH 3.5 (mV) | | | | |

### Examples 34-38: Testing of Centrifuged CMP Polishing Compositions

Particles containing cationic sulfur onium groups were used to polish a silica (TEOS) wafer and compared to unmodified silica particles. To minimize sulfur oniums freely floating in solution or loosely associated with the silica particles, the particles were first isolated by centrifugal ultrafiltration of the CER treated acidified particle solution, as described above in Examples 30-33, but using an Amicon™ Ultra-15 (larger volume centrifugal filtration unit, Millipore Sigma). They were then ultrafiltered with 10 grams of pH 3.5 water twice more before polishing. The final polishing composition was made by resuspending the filtered particles in 12 grams of pH 3.5 deionized water, using nitric acid to acidify. The % solids, zeta potential, and number-average particle diameter were measured after the filtration and resuspension processes. As shown in Table 8, below, the inventive compositions showed a much enhanced TEOS removal rate versus the comparative example(s), even with very low solids loading.

TABLE 8
CMP Polishing using Centrifuged Slurry Compositions

| | Example# | | | | |
|---|---|---|---|---|---|
| | Comp Ex 34 | Ex 35 | Ex 36 | Ex 37 | Ex 38 |
| Particles used | Slurry A | Ex 26 | Ex 27 | Ex 28 | Ex 29 |
| Particles in | NA | 12.82 | 13.73 | 14.01 | 13.24 |
| Amicon-15 tube (g) | | | | | |
| pH of polish | 3.5 | 3.5 | 3.5 | 3.5 | 3.5 |
| Number average | — | 41.6 | 30.1 | 37.1^{a} | 39.2^{a} |
| particle diameter of | | | | | |
| polishing | | | | | |
| composition (nm) | | | | | |
| Zeta potential of | — | 0.24 | 12.4 | −1.23^{a} | 11.3^{a} |
| polishing | | | | | |
| composition (mV) | | | | | |
| % silica in polishing | 1.98 | 0.91 | 0.70 | 2.65 | 1.76 |
| composition | | | | | |
| TEOS Removal | 138^{b} | 244 | 490 | 311 | 625 |
| rate (Ang/min) | | | | | |

^{a}The measurements were done on 1 gram of polishing composition combined with 2 grams of pH 3.5 water;
^{b}Reported removal rate is the average of 2 separate polishes of the slurry.

### Examples 39-45: Comparative CMP Polishing Compositions

A set of comparative examples was prepared using Silica Dispersion A, water, and various amounts of added sulfur onium species as below. The pH was adjusted as needed to pH 3.5 using dilute nitric or potassium hydroxide solutions. In the Comparative Examples 39-45, the sulfur onium compounds are merely mixed with Slurry A. As shown in Table 9, below, when the dispersions were used to polish a silica (TEOS) wafer, the removal rates were not significantly improved by the presence of small amounts of freely floating sulfur onium species. In Table 9, below, the term “Amount of Comp. Ex. 39 and 40” phrases refer to the use of comparative examples 39 and 40, which are 50 ppm in trimethylsulfoxonium and trimethylsulfonium, respectively, as solutions to prepare the more dilute comparative examples 41-45.

TABLE 9
CMP Polishing using Comparative Slurry Compositions

| | Comp | Comp | Comp | Comp | Comp | Comp | Comp |
|---|---|---|---|---|---|---|---|
| | Ex 39 | Ex 40 | Ex 41 | Ex 42 | Ex 43 | Ex 44 | Ex 45 |
| Water (g) | 173.32 | 173.32 | 13.00 | 23.4 | 13.00 | 23.4 | 26.00 |
| Silica Dispersion A (g) | 26.66 | 26.66 | 2.0 | 3.60 | 2.0 | 3.60 | 4.00 |
| Trimethylsulfoxonium Iodide | 0.010 | 0 | 0 | 0 | 0 | 0 | 0 |
| (g) | | | | | | | |
| Trimethylsulfonium iodide (g) | 0 | 0.010 | 0 | 0 | 0 | 0 | 0 |
| Amount Comp Ex 39 (g) | 0 | 0 | 15.00 | 3.00 | 0 | 0 | 0 |
| Amount Comp Ex 40 (g) | 0 | 0 | 0 | 0 | 15.00 | 3.00 | 0 |
| Silica % | 2 | 2 | 2 | 2 | 2 | 2 | 2 |
| Trimethylsulfoxonium iodide | 50 | 0 | 25 | 5 | 0 | 0 | 0 |
| (ppm) | | | | | | | |
| Trimethylsulfonium iodide | 0 | 50 | 0 | 0 | 25 | 5 | 0 |
| (ppm) | | | | | | | |
| Solution pH | 3.5 | 3.5 | 3.5 | 3.5 | 3.5 | 3.5 | 3.5 |
| Zeta potential at 2% silica, pH | −11.9 | −10.7 | −14.50 | −14.9 | −13.0 | −14.9 | −14.7 |
| 3.5 (mV) | | | | | | | |
| TEOS Removal rate (Ang/min) | 83 | 103 | 135 | 126 | 96 | 105 | 104 |

I claim:

1. An aqueous chemical mechanical planarization (CMP) polishing composition comprising: from 0.25 to 30 wt. % of aqueous colloidal silica particles containing within them trialkylsulfonium groups, trialkylsulfoxonium groups, or both, the compositions having a pH of from 2 to 7, and, further wherein, the particles have a zeta potential of from −2 mV to 40 mV at a pH of 3.5 and a solids content of 2 wt. %.

2. The aqueous chemical mechanical planarization (CMP) polishing composition as claimed in claim 1, wherein the aqueous colloidal silica contain within them trimethylsulfoxonium groups, trimethylsulfonium groups, or both.

3. The aqueous chemical mechanical planarization (CMP) polishing composition as claimed in claim 1, wherein the alkyl groups in the trialkylsulfonium or trialkylsulfoxonium groups comprise, independently C₁ to C₄ alkyl groups, or C₁ to C₄ branched alkyl groups.

4. The aqueous chemical mechanical planarization (CMP) polishing composition as claimed in claim 1, wherein the compositions have a zeta potential of from 1 to 20 mV at a pH of 3.5 and a solids content of 2 wt. %.

5. The aqueous chemical mechanical planarization (CMP) polishing composition as claimed in claim 1, wherein the aqueous colloidal silica particles further contain one or more aminosilane groups.

6. The aqueous chemical mechanical planarization (CMP) polishing composition as claimed in claim 5, wherein the aqueous aminosilane comprises an aminosilane containing one or more tertiary amine group or one or more secondary amine group.

7. The aqueous chemical mechanical planarization (CMP) polishing composition as claimed in claim 1, wherein the z-average particle sizes (DLS) of the colloidal silica ranges from 24 nm to 250 nm.

8. The aqueous chemical mechanical planarization (CMP) polishing composition as claimed in claim 1, the compositions further comprising nitric acid or KOH in an amount to adjust the pH.

9. A method of making an aqueous CMP polishing composition comprising: (a1) providing aqueous silicic acid at a pH of below 4.0 at a solids concentration of from 1 to 20 wt. %, or (a2) forming the aqueous silicic acid at the same solids concentration as in (a1) by combining an excess of an aqueous cation exchange resin in protonated form containing an acid functional group with a silicic acid alkali salt, in solid form or as an aqueous dispersion of from 5 to 50 wt. % solids so as to keep the dispersion below a pH of 9 and allowing the pH to drop as the alkali metal is consumed by the cation exchange resin; separately, providing a reactive aqueous colloidal silica dispersion at a solids content of from 2 to 20 wt. % solids and a pH of from 2.1 to 4; adding a trialkylsulfonium or trialkylsulfoxonium salt or hydroxide, or a mixture thereof to the reactive aqueous colloidal silica dispersion to form a reaction mixture; heating the reaction mixture to a reaction temperature of from 70 to 120° C., feeding the aqueous silicic acid in to the reaction mixture over a time of from 30 to 900 minutes to create a partially reacted dispersion of the silicic acid and the colloidal silica; rapidly adjusting the pH of the reaction mixture to a pH of from 8 to 10 to form a basic reaction mixture; and, heating the basic reaction mixture to a temperature of from 70 to 120° C. to polymerize the silicic acid.

10. A method of making an aqueous CMP polishing composition comprising: (a1) providing aqueous silicic acid at a pH of below 4.0 and at a solids concentration of from 1 to 20 wt. %, or (a2) forming the aqueous silicic acid at the same solids content as in (a1) by combining an excess of an aqueous cation exchange resin in protonated form containing an acid functional group with a silicic acid alkali salt in solid form or as an aqueous dispersion of from 5 to 50 wt. % solids to keep the dispersion below a pH of 9 and allowing the pH to drop as the alkali metal is consumed by the cation exchange resin; separately, providing a reactive aqueous colloidal silica dispersion at a solids content of from 2 to 20 wt. % solids and at a pH of from 7 to 11; adding a trialkylsulfonium or trialkylsulfoxonium salt or hydroxide, or a mixture thereof to the reactive aqueous colloidal silica dispersion to form a reaction mixture; heating the reaction mixture to a temperature of from 70 to 120° C., feeding the aqueous silicic acid in to the reaction mixture over a time of from 30 to 900 minutes; optionally, co-feeding a base during the feeding of the silicic acid to maintain a desired pH range; and optionally, allowing the reaction mixture to react at a temperature of from 70 to 120° C. for an additional 30 to 900 minutes after the feeds have completed.
